(19) United States
(12) Patent Application Publication
(10) Pub. No.: US 2007/0128458 A1
(43) Pub. Date: Jun. 7, 2007

(54) Protection of metallic surfaces against thermally-inducted wrinkling (rumpling)

(75) Inventors: Marion Bartsch, Koln (DE); Bernd Baufeld, Leuven (BE)

Correspondence Address: HARNESS, DICKEY & PIERCE, P.L.C., P.O. BOX 828, BLOOMFIELD HILLS, MI, 48303, US

(73) Assignee: DUETSCHES ZENTRUM FUR LUFT-UND RAUMFAHRT E.V., KOLN (DE)

(21) Appl. No.: 10/573,667

(22) PCT Filed: Sep. 29, 2004
(86) PCT No.: PCT/EP04/10887

§ 371 Date: Nov. 20, 2006

(30) Foreign Application Priority Data
Oct. 1, 2003 (DE) 103 45 738.0

(51) Int. Cl. C23C 14/32; C23C 16/00; B05D 3/02; B05D 1/18; B05D 1/08; B32B 15/04

(52) U.S. Cl. 428/469; 427/446; 427/248.1; 427/430.1; 427/372.2; 204/192.1; 428/336

(57) ABSTRACT

Gas turbine blades in power units or for electric power generation are subject to high thermal stress which is cyclic in nature and leads to a roughening of the metallic surface. According to the invention, the metallic surface is provided with a thin ceramic coating having a thickness of less than 50 μm. Roughening can be avoided thereby.

The invention relates to a metallic component with a ceramic coating and to a process for preparing said coating as well as to the use of such coating for the protection of metallic surfaces from thermally influenced wrinkling (rumpling).

Metal surfaces which are subjected to high thermal and mechanical alternating stress may exhibit wrinkling (rumpling) of the surface. This is observed, for example, at the surfaces of gas turbine blades which are provided with a metallic oxidation protection coating. The wrinkling is a roughening of the surface and may lead to a reduction of the effectiveness and service life of the component. Especially in the case of a metallic oxidation protection coating on gas turbine blades, the roughening has the following negative effects:
the aerodynamic efficiency is reduced;
cracks proceed from the roughness valleys and propagate into the blade material and may lead to failure;
the roughening increases the surface area of the protection coating, so that the oxidation of the protection coating material is accelerated, and the protective function exhausted prematurely.
   An essential cause of the roughening of metallic surfaces under service conditions is mechanical instabilities of the zones close to the surface from pressure stress parallel to the surface. When the yield stress is exceeded, the surface is subjected to plastic deformation, and such plastic deformations accumulate when the stress is cyclic in nature. High pressure stress in zones close to the surface is produced, for example, by temperature gradients between the outer and inner walls of components cooled from inside.

To date, it has been tried to achieve a reduction or delay of rumpling in metallic protection coatings for gas turbine blades by modifying their chemical composition. The chemical composition of the metallic surface protection coating is changed in such terms that a high creep resistance is achieved at high temperatures and on the other hand, a sufficient ductility is retained at low temperatures to limit the formation of cracks proceeding from the surface of the protection coating. Patents: [U.S. Pat. No. 5,958,204; Creech et al., 28th Sep. 1999, Enhancement of coating uniformity by alumina doping], [U.S. Pat. No. 6,153,313; Rigney et al., 28th Nov. 2000, Nickel aluminide coating and coating systems formed therewith], [U.S. Pat. No. 5,277,936; Olson et al., 11th Jan. 1994, Oxide containing MCrA1Y-type overlay coatings].

Further, it is known to provide metallic work pieces with thick ceramic layers for the purpose of heat insulation in very severely thermally stressed parts of power units, engines and gas turbines for electric power generation. The heat insulation layers on turbine blades of power units usually have a thickness of at least from 100 μm to 200 μm. In other fields of application, the thickness is even greater. It may be as great as several millimeters. As a side effect, thick ceramic heat insulation layers prevent thermally influenced wrinkling. There are cases in which the application of heat insulation layers to metallic surfaces is precluded, for example, because they would impede the dissipation of heat from the surfaces or adversely affect the function of the component by the additional mass and/or geometric changes.

DE 40 28 173 A1 describes a layer system for thermal insulation consisting of yttrium-stabilized zirconia with a layer thickness of about 25.4 to about 508 μm.

EP 1 111 085 A1 describes a layer system for thermal insulation having a total layer thickness of from 0.05 to 5000 μm, wherein at least one of the layers may also consist of stabilized zirconia.

WO 01/23642 A2 describes a layer system for thermal insulation consisting of different oxides, mainly of rare earth metals, having a layer thickness of from 50 to 500 μm.

U.S.Pat. No. 4,405,660, Example 1, describes a layer system for thermal insulation consisting of yttrium-stabilized zirconia with a layer thickness of about 127 μm.

It is the object of the invention to provide an article with a ceramic coating, a process as well as the use of said coating for the protection of highly stressed metallic surfaces from thermally influenced wrinkling (rumpling).

The metallic component according to the invention is defined in claim 1. Thus, the surface is provided with a thin ceramic coating having a thickness of less than 50 μm.

Thus, the invention relates to a metallic component for use under thermal and mechanical stress which leads to a risk of thermally influenced wrinkling (rumpling), having a coating of ceramic material which covers its surface at least partially. According to the invention, this component is characterized in that the thickness of the coating is smaller than 50 μm, especially smaller than 30 μm, more preferably smaller than 20 μm.

Surprisingly, it has been found in the selected layer thickness range of up to 50 μm that although substantially no heat-insulating effect was observed due to the low layer thickness, but unexpectedly an effect against thermally influenced wrinkling (rumpling) was observed.

Surprisingly, it has been found that thin ceramic layers or less already effectively and permanently prevent roughening of the surface.

According to the invention, it is suggested to prevent roughening of the surfaces by applying a thin ceramic layer. Ceramics often have a higher rigidity at high temperatures and thus a significantly higher yield or creep stress as compared to metals, so that they can prevent roughening, i.e., the non-elastic deformation of the metal surface. The roughening can be effectively suppressed already by very thin layers having a thickness of about 20 μm. Even under extreme conditions, such as a high pressure stress in the region of the surface, the roughening of the surface is prevented with thin layers of about 20 μm. The effectiveness of the thin ceramic layer is retained for the whole service life of the layer.

Advantageously, the metallic surface to be coated already has an oxidic coating. Thus, the adhesion to the metallic substrate can be further improved.

Preferably, the thickness of the ceramic coating is less than 30 μm, especially less than 25 μm and most preferably less than 20 μm. The small layer thickness has the advantage that the application can be effected more quickly and with lower cost. Further, coating methods which are unsuitable for producing thick layers can be employed. In addition, the structure and function of the component are changed but slightly.

Preferably, the surface to be coated consists of an aluminum-containing metallic oxidation protection coating. The oxidation protection coating causes a protecting alumina layer to grow. This improves the adhesion of the ceramic coating. Its thickness is usually 0.5μm as grows during service.

The ceramic coating preferably consists of an oxidic ceramic material, for example, based on ZrO₂.

Preferably, the thickness of the ceramic coating is at least 5 μm, especially at least 10 μm. Thus, a high conformity and continuity of the layer can be ensured in which the desired effect against thermally influenced wrinkling (rumpling) can still be observed.

The invention further relates to the preparation of the thin ceramic coating. It can be effected with methods like EB-PVD or APS. Other coating methods, such as CVD, electrophoresis followed by microwave sintering or dip coating with ceramic precursors may also be employed because of the small layer thickness.

In a further embodiment, the object of the invention is achieved by the use of the coating of the metallic component according to the invention as a layer against thermally influenced wrinkling (rumpling).

The invention is suitable for metallic components which are subjected to high mechanical stress or hydrodynamic stress and high thermal stress, especially when the thermal stress is cyclic in nature.

The invention is suitable for rotors and stators of turbo engines, especially for gas turbine blades of power units or of stationary gas turbines for electric power generation.

In the following, a special Example of the invention is explained in more detail.

To a specimen made of a nickel-based superalloy with an oxidation protection coating of NiCoCrA1Y, a ceramic ZrO₂ layer was applied by means of EB-PVD in part of the surface. This ceramic layer had a thickness of about 25 μm. Upon cyclic stress between 20° C. and 1080° C., a clear roughening could be detected after 10cycles on the uncoated portions of the NiCoCrAlY layer. In contrast, the portions covered with a thin ZrO₂ layer remained smooth.

The specimen was a cylindrical hollow specimen. During the thermomechanical experiment, temperature and mechanical load cycles were applied simultaneously. By cooling the inner wall of the specimen with air and heating the outer wall of the specimen with a radiation furnace, a temperature gradient was additionally produced through the wall of the specimen, which produces pressure stress in the outer wall parallel to the surface similar to that experienced in gas turbine blades.

1. Use of a ceramic coating having a thickness of less than 50 μm on a metallic component for preventing thermally influenced deformation in metallic components.

2. A metallic component for use under thermal and mechanical stress which leads to a risk of thermally influenced deformation, having a coating of ceramic material which covers its surface at least partially, characterized in that the thickness of the coating is up to 30 μm.

3. The metallic component according to claim 2, characterized in that the coated metallic surface already has an oxidic coating.

4. The metallic component according to claim 2, characterized in that the coated surface consists of an aluminum-containing metallic oxidation protection coating.

5. The metallic component according to claim 2, characterized in that the thickness of the ceramic coating is less than 20 μm.

6. The metallic component according to claim 2, characterized in that the ceramic coating consists of an oxidic ceramic material.

7. The metallic component according to claim 2, characterized in that the thickness of the ceramic coating is at least 10 μm.

8. A process for the preparation of a metallic component, characterized in that its surface is provided with a thin ceramic coating having a thickness of up to 30 μm.

9. The process according to claim 8, characterized in that said coating is produced by electron beam physical vapor deposition (EB-PVD) or air plasma spraying (APS).

10. The process according to claim 8, characterized in that said coating is produced by chemical vapor deposition (CVD), electrophoresis followed by microwave sintering, or dip coating with ceramic precursors followed by sintering.
